(19) United States
(12) Patent Application Publication
(10) Pub. No.: US 2004/0018715 A1
(43) Pub. Date: Jan. 29, 2004

(54) Method of cleaning a surface of a material layer

(75) Inventors: Bingxi Sun, Stanford, CA (US); David M. Pung, Portland, OR (US); Ashish Bodke, Sunnyvale, CA (US); Nety M. Krishna, Sunnyvale, CA (US)

Correspondence Address: PATENT COUNSEL, APPLIED MATERIALS, INC., Legal Affairs Department, P.O. Box 450A, Santa Clara, CA, 95052, US

(73) Assignee: Applied Materials, Inc.

(21) Appl. No.: 10/205,762

(22) Filed: Jul. 25, 2002

(51) Int. Cl. H01L 21/44; H01L 21/4763

(52) U.S. Cl. 438/622; 438/624

(57) ABSTRACT

A method for removing a reducible contaminant, such as an oxide or organic material, from a surface of a material layer comprises contacting an exposed dielectric layer with one or more suppressant species. The exposed dielectric layer and the material layer are contacted with the reducing species. Contacting the exposed dielectric layer with the suppressant species suppresses reactions between the exposed dielectric layer and the reducing species. Contacting the dielectric layer with the suppressant species may prevent the reducing gas from increasing the dielectric constant of the dielectric layer.

### BACKGROUND OF THE INVENTION

1. Field of the Invention

Embodiments of the present invention generally relate to cleaning the surface of a material layer and, more particularly, a method of cleaning a surface of a material layer during an integrated circuit fabrication process.

2. Description of the Related Art

Integrated circuits have evolved into complex devices that can include millions of components (e.g., transistors, capacitors and resistors) on a single chip. The evolution of chip designs continually requires faster circuitry and greater circuit density. The demands for greater circuit density necessitate a reduction in the dimensions of the integrated circuit components.

As the dimensions of the integrated circuit components are reduced (e.g., sub-micron dimensions), the materials used to fabricate such components increasingly contribute to their electrical performance. For example, low resistivity metal interconnects (e.g., copper and aluminum) provide conductive paths between the components on integrated circuits. Typically, the metal interconnects are electrically isolated from each other by an insulating material. When the distance between adjacent metal interconnects and/or the thickness of the insulating material has sub-micron dimensions, capacitive coupling potentially occurs between such interconnects. Capacitive coupling between adjacent metal interconnects may cause cross talk and/or resistance-capacitance (RC) delay which degrades the overall performance of the integrated circuit. In order to prevent capacitive coupling between adjacent metal interconnects, low dielectric constant (low k) dielectric materials (e.g., dielectric constants less than about 4) are needed.

Interconnect structures are typically fabricated by forming a series of dielectric layers and conductive layers in order to create a three dimensional network of conductive layers separated by dielectric material. The interconnect structure may be fabricated using, for example, a damascene structure in which a dielectric layer such as a low k dielectric layer is formed atop one or more conductive plugs or sub-layers. In order to form an electrical connection to the conductive sub-layers, the dielectric is patterned and etched to define via openings therethrough. Formation of the openings within the dielectric layer exposes the conductive sub-layers.

Before expanding the interconnect structure by depositing an additional layer of conductive material, it is desirable to clean the top surface of the conductive sub-layer in order to remove residual contaminants such as oxides and organic material. Removal of the contaminants from the top surface of the exposed conductive sub-layer before depositing subsequent conductive material serves to prevent any increase in contact resistance or prevent adhesion loss that would result from the presence of contaminants at the interface of the conductive sub-layer and the conductive material to be deposited.

Conventional cleaning processes for removing contaminants from a surface of conductive material typically employ the use of a reducing agent, such as hydrogen, alone or in combination with physical sputtering. Unfortunately, reducing agents, such as hydrogen, have been found to cause undesirable changes in many dielectric materials used in interconnect structures. This is particularly the case for many dielectric materials that have a low dielectric constant (i.e., low K dielectrics). Such materials are susceptible to “k loss,” in which the dielectric constant of the low K dielectric is increased after exposure to the reducing agent used in the cleaning procedure. As a result, undesirable cross-talk and RC delay become more problematic after the cleaning procedure.

Therefore, a need exists for a method of cleaning conductive material on a substrate wherein the method does not adversely affect the dielectric properties of an exposed dielectric layer.

### SUMMARY OF THE INVENTION

The present invention generally provides a method of removing a reducible contaminant from a surface of a material layer. The material layer may be a conductive layer such as copper. A dielectric layer is exposed to one or more suppressant species. The suppressant species may comprise, for example oxygen, hydrogen, nitrogen, carbon, or combinations thereof. The dielectric layer and the contaminant are then exposed to a reducing species. The reducing species removes the reducible contaminant from the material layer. The exposure of the dielectric layer to the suppressant species protects the dielectric layer from reactions with the reducing species. Exposing the dielectric layer to the suppressant species may prevent the reducing gas from increasing the dielectric constant of the dielectric layer. The reducing species may comprise, for example, hydrogen.

In another embodiment of the invention, a method of cleaning a surface of a material layer having a reducible contaminant thereon comprises exposing the surface of the material layer to a plasma. The plasma comprises a reducing species and one or more suppressant species. Suppressant species in the plasma protect a dielectric layer that may be exposed to the plasma by preventing reactions between the dielectric layer and the reducing species. The reducing species clean the reducible contaminant, such as an oxide, from the surface of the material layer.

In another embodiment of the invention, a method of cleaning a surface of a conductive sub-layer within a feature formed in a dielectric layer comprises forming a plasma comprising a reducing species and one or more suppressant species. The suppressant species protect an exposed portion of the dielectric layer (e.g. sidewalls of the feature) from reactions with the reducing species.

In another embodiment of the invention, a method for pre-treating a dielectric layer comprises exposing the dielectric layer to one or more suppressant species for suppressing reactions between the dielectric layer and a reducing species. The suppressant species may comprise at least one element selected from the group consisting of carbon, oxygen, hydrogen, and nitrogen. The pre-treatment of the dielectric layer with the suppressant species protects the dielectric layer from reactions with the reducing gas.

In another embodiment of the invention, a method of removing a contaminant from a surface of a material layer comprises exposing the contaminant to an oxide of carbon, such as carbon monoxide. The oxide of carbon reacts with the reducible contaminant to remove the contaminant from the surface of the material layer.

In another embodiment of the invention, a method of forming an interconnect for an integrated circuit comprises depositing a dielectric layer on a substrate that includes a conductive sub-layer. A feature is etched within the dielectric layer to expose a surface of the conductive sub-layer. A surface of the conductive sub-layer is cleaned with a plasma comprising a reducing gas and one or more suppressant gases for suppressing reactions between the reactant gas and the dielectric layer. Conductive material is then deposited within the feature.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a reactive pre-clean chamber that is coupled to a remote plasma source for cleaning features according to embodiments described herein;

FIG. 2 is an alternate embodiment of a reactive pre-clean chamber that may be used to practice embodiments of the invention described herein; and

FIGS. 3A-3I are cross-sectional views of a substrate during different stages of an integrated circuit fabrication sequence.

### DETAILED DESCRIPTION

The present invention generally provides a method of cleaning a layer having a reducible contaminant thereon. The method may comprise the steps of exposing the material layer to a plasma comprising a reducing species and one or more suppressant species for suppressing a reaction between an exposed dielectric layer and the reducing species.

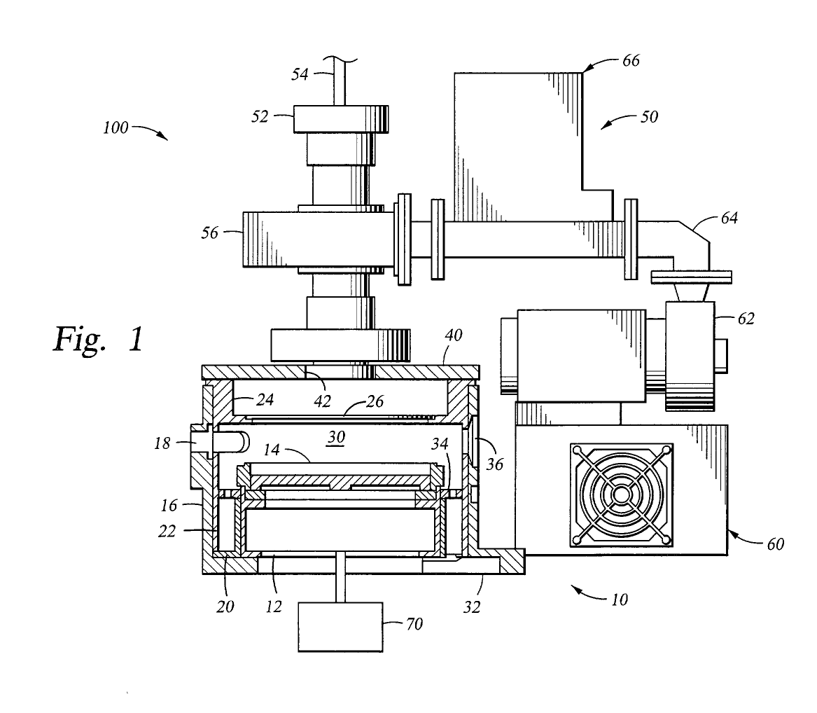

FIG. 1 is a schematic illustration of a reactive pre-clean apparatus 100 (RPC apparatus) that comprises a reactive pre-clean chamber 10 (RPC chamber) and a remote plasma source 50.

Referring to FIG. 1, the RPC chamber 10 has cathode pedestal 12 coupled to a chuck 14 such as an electrostatic chuck that secures the substrate (not shown) to the cathode pedestal 12. A high frequency power source 70, such as an RF power supply may be coupled to the cathode pedestal 12 in order to form a negative bias thereon. The RPC chamber 10 includes a chamber body 16 having a slit valve port 18 which connects the chamber 10 to a substrate processing platform.

The cathode pedestal 12 is shielded from process gases by a cathode liner 20 which has a non-stick outer surface to enhance process performance. The chamber body 16 is also shielded from process gases by a chamber liner 22 which has a non-stick inner surface to enhance process performance. The chamber liner 22 may include an inner annular ledge 24 which supports a gas distribution plate 26. The gas distribution plate 26 may have a plurality of spaced holes which distribute process gases received from a remote plasma source 50 described below. The process gases flow over the surface of a substrate positioned on the chuck 14. The remote plasma source 50 typically confines any plasma of the process gases and provides energized neutral or charged species to the chamber 10. The gas distribution plate 26 may be grounded to reduce ions remaining in the process gases.

A processing region 30 above the cathode pedestal 12 is maintained at a low process pressure by vacuum pumps (not shown) which are in fluid communication with an exhaust port 32 on the chamber body 16. A plenum 34 having a plurality of spaced holes separates the processing region 30 from the exhaust port 32 to promote uniform exhausting around the cathode pedestal 12. The processing region 30 is visible from outside the chamber 10 through a sapphire window 36 which is sealed in the chamber body 16.

The chamber 10 generally has a removable chamber lid 40 which rests on the chamber liner 22. The chamber lid 40 may have a central injection port 42 which receives process gases from the remote plasma source 50.

Referring to FIG. 1, process gases for the cleaning process of the present invention are excited into a plasma within the remote plasma source 50 which is in fluid communication with the RPC chamber 10 described above. The process gases generally include a reducing gas to react with reducible contaminants, such as thin layers of oxide, hydrocarbon, fluorocarbons, and the like, that may be present on a material layer. The remote plasma source 50 comprises a plasma applicator 52 that has a gas inlet 54 for receiving process gases. The process gases flow through the applicator 52 and are ignited into a plasma within the applicator 52. The plasma exits the applicator 52 and moves into the central injection port 42 in the chamber lid 40. A jacket waveguide 56 surrounds a sapphire tube portion of the plasma applicator 52 and supplies microwave energy to the process gases.

High frequency energy such as microwave energy is generated by a magnetron 60 which may provide up to about 5 kilowatts (kW) at a frequency of about 2.45 GHz. Alternatively, the high frequency energy may be radio frequency (RF) energy generated by an RF source (not shown). The RF source may provide RF energy having a power within a range of about 1 KW to about 20 kW. The RF energy may have a frequency of about 13.56 megahertz (MHz). The high frequency energy passes through an isolator 62 which prevents reflected power from damaging the magnetron 60. The energy from the isolator 62 may be transmitted through a waveguide 64 to an autotuner 66 which automatically adjusts the impedance of the plasma in the applicator 52 to the impedance of the magnetron 60 resulting in minimum reflected power and maximum transfer of power to the plasma applicator 52.

Although reactive precleaning is described with reference to FIG. 1 preformed in a dedicated precleaning chamber, the precleaning could also be done by connecting the remote plasma source 50 to a deposition chamber such as a plasma enhanced chemical vapor deposition (PECVD) or a physical vapor deposition (PVD) chamber. For example, gas inlets could be provided at the level of the substrate in such chambers to deliver activated chemical species generated in the remote plasma source 50. A deposition chamber, such as a chamber used to deposit a conductive material, having gas delivery systems may be modified to deliver the activated chemical species through existing gas inlets such as a gas distribution showerhead positioned above the substrate.

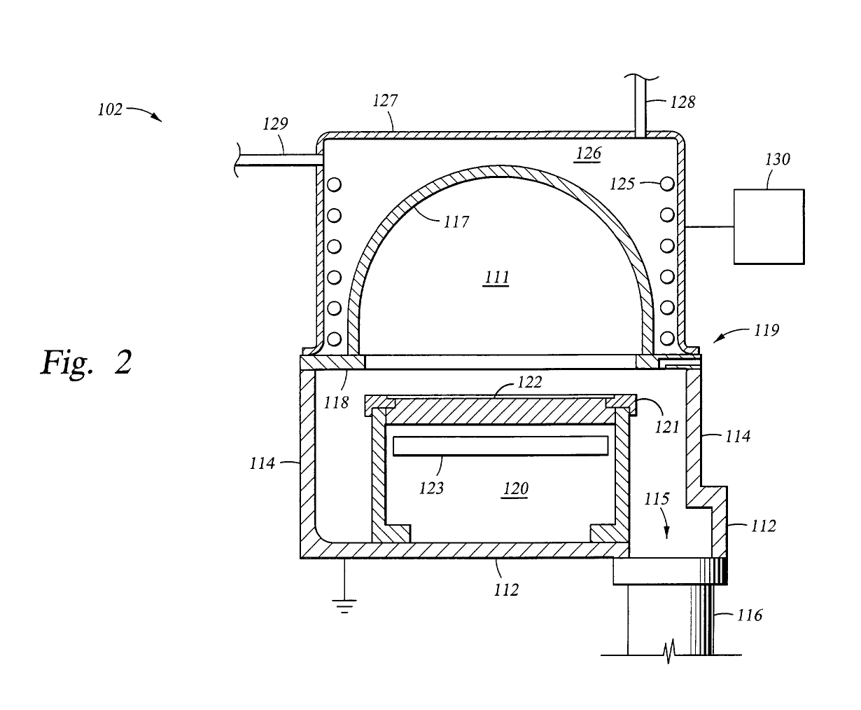

FIG. 2 is a schematic sectional view of an alternative RPC apparatus 102 that may be used to practice embodiments described herein. The RPC apparatus 102 may be a Preclean II chamber which is available from Applied Materials, Santa Clara, Calif. The RPC apparatus 102 comprises a vacuum chamber 111 formed by a base member 112 having sidewalls 114 which are preferably made of metallic construction such as stainless steel, aluminum or the like. An opening 115 in the base of the body member 112 is connected to a turbo pump 116 which is used to control the gas pressure inside the chamber 111. A quartz dome 117 forms the top of the chamber 111 and is provided with a flange 118 about its circumference where it mates with the top circumference of the sidewalls 114 of base member 112. A gas distribution system 119 is provided at the juncture of quartz dome 117 and the base member 112. An insulating pedestal 120 made of quartz, ceramic or the like has a quartz cover 121 holding down a conductive pedestal 122 which is arranged to hold a wafer in the chamber 111. A high frequency power supply 123, such as an RF power supply, is capacitively coupled to the pedestal 122 and supplies a negative bias voltage thereto.

An antenna 125 such as an RF induction coil is wound exteriorly to quartz dome 117 to control the plasma density in the chamber 111. The antenna 125 is supported by a cover 127. The antenna 125 may be formed of hollow copper tubing. An alternating axial electromagnetic field is produced in the chamber 111 interiorly to the windings of the antenna 125. Generally, an RF frequency of from about 400 kHz to about 13.56 MHz is employed and an RF power supply 130 of conventional design (not shown) operating at this frequency is coupled to the antenna 125 by a matching network (not shown) to generate a plasma in the chamber 111. The high frequency electromagnetic field generates a plasma within the portion of the chamber 111 above the pedestal 122. A vacuum is drawn inside the chamber 111 and process gases are pumped from one or more gas sources (not shown) through a gas inlet 129 into the chamber 111. An exhaust outlet 128 may be used to vent gases outside the chamber 111.

The RPC apparatus, such as RPC apparatus 100 or RPC apparatus 102 may be integrated with other process chambers on a processing platform (not shown) to avoid interim contamination of the substrates. The processing platform may include one or more deposition chambers, such as, for example, one or more PVD chambers or chemical vapor deposition (CVD) chambers for depositing dielectric layers, such as low K dielectric layers, or other material layers including conductive layers, seed layers, barrier layers, among other material layers. The platform may comprise other processing chambers, such as etch chambers, transfer chambers and the like.

Method of Cleaning

In one embodiment of the invention, a method of cleaning a surface of a material layer having a reducible contaminant thereon comprises exposing a dielectric layer to one or more suppressant species for suppressing reactions between the dielectric layer and a reducing species. The exposed dielectric layer and the surface of the material layer are then contacted with the reducing species.

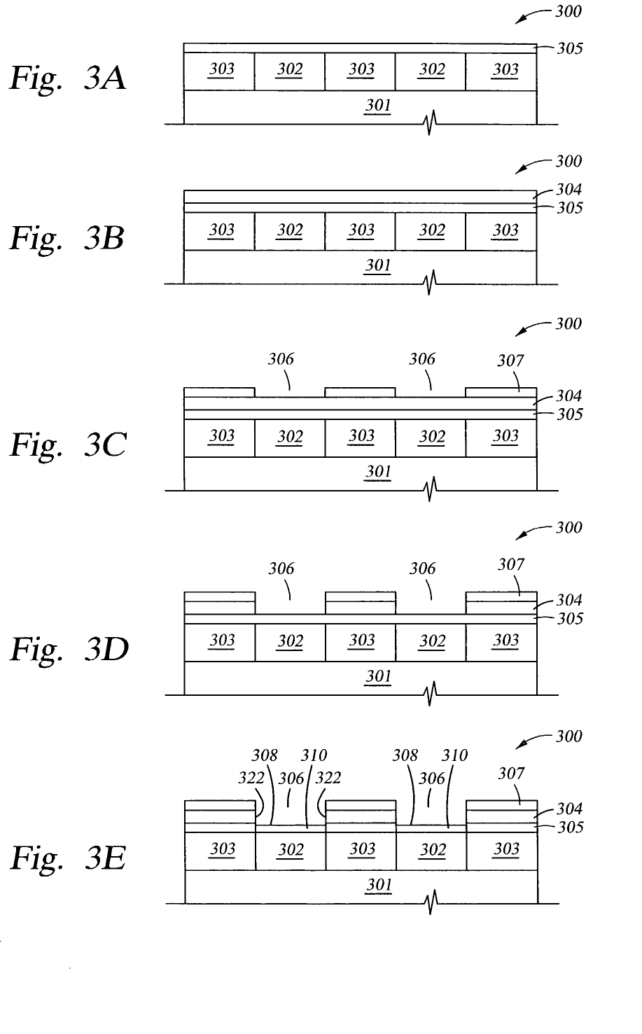

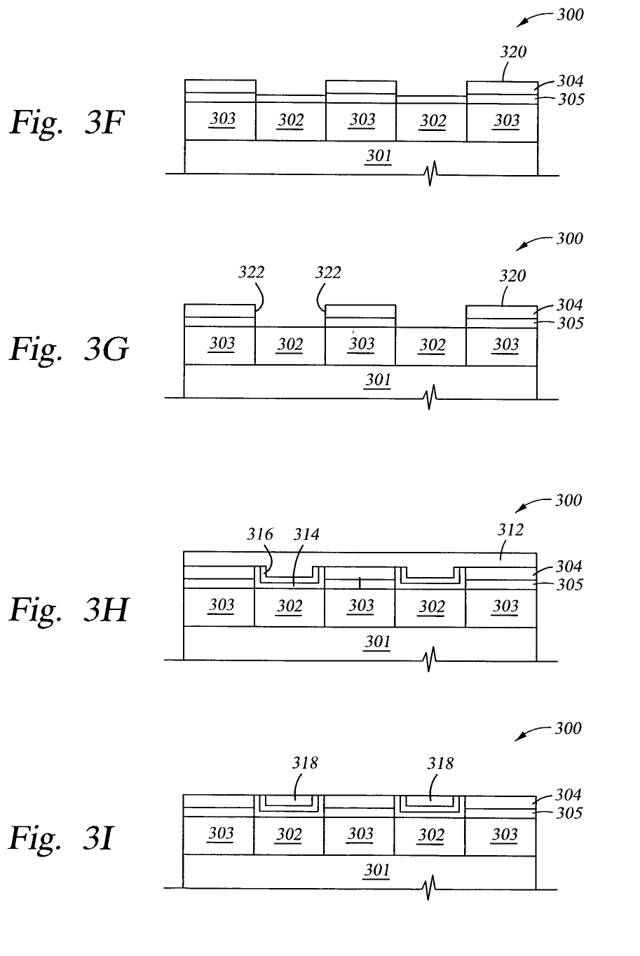

FIG. 3 is a cross-sectional view of a substrate 300 during different stages of an integrated circuit fabrication sequence. The substrate 300 refers to any workpiece on which film processing is performed. Depending on the specific stage of processing, the substrate 300 may correspond to a silicon wafer, or other material layers, which have been formed thereon. In the exemplary fabrication process depicted in FIG. 3, the substrate 300 comprises a plurality of conductive sub-layers 302 formed on a material layer 301. The material layer 301 may be, for example, a dielectric, a semiconducting layer, a wafer substrate, etc. As indicated in FIG. 3A, the conductive sub-layers 302 are adjacent to material sub-layers 303, that may be, for example, dielectric layers. An optional etch stop layer 305 may be formed over the material sub-layers 303 and the conductive sub-layers 302. The optional etch stop layer may comprise, for example, silicon nitride (Si₃N₄). he conductive sub-layers 302 may comprise a material such as, for example, copper (Cu), aluminum (Al), or tungsten (W).

As shown in FIG. 3B, a dielectric layer 304 is deposited on the etch stop layer 305 on the substrate 300 using conventional methods, such as, for example, chemical vapor deposition (CVD), plasma enhanced chemical vapor deposition (PECVD), spin coating, physical vapor deposition (PVD) among other deposition methods. The dielectric layer 304 may comprise a conventional dielectric material, such as silicon dioxide, silicon nitride, aluminum oxide, and the like. Alternatively, the dielectric layer may be a low K dielectric layer. Examples of low K dielectric materials include, fluorine-doped silicate glass (FSG), xerogels and other porous oxide materials, silsesquioxanes, organosilicates, parylene, fluorinated materials, among other low K dielectrics. In at least one embodiment, the low K dielectric material comprises carbon. The low K dielectric may have a dielectric constant less than about 4.0.

Referring to FIG. 3C, the dielectric layer 304 is patterned using conventional patterning technology (e.g. photoresist processing). An etch resist 307 is deposited on the dielectric layer 304 and patterned to define regions for etching features 306 into the dielectric layer 304. The feature 306 may be, for example, a sub-micron feature. Referring to FIG. 3D, the features 306 are extended into the dielectric layer 304 by etching the dielectric layer 304, using, for example, a reactive ion etch process. A suitable etchant may be selected based upon the composition of the dielectric layer 304. Exemplary etchants include, fluorocarbons, hydrofluorocarbons, sulfur compounds, oxygen, nitrogen, carbon dioxide, etc. At least one feature 306 is aligned with a conductive sub-layer 302 such that contact may be made thereto. For embodiments in which an optional etch stop layer 305 has been formed atop the conductive sub-layer 302, the etch stop layer 305 may be removed by a suitable etchant in order to expose the conductive sub-layer 302, as shown in FIG. 3D. For example, to remove a silicon nitride etch stop layer 305, a reactive ion etch process wherein a plasma comprising such oxygen and/or fluorocarbons may be used to etch portions of the optional etch stop layer 305 in order expose the conductive sub-layer 302.

Referring to FIG. 3E, the feature 306 is etched to a depth sufficient to expose a surface 308 of the feature 306. The surface 308 of the feature 306 generally has a contaminant region 310 (may be exaggerated in size for clarity) associated with the surface 308. The contaminant region 310 may comprise, for example, an oxide such as a metal oxide, organic residues, or combinations thereof. The organic residues may comprise, for example, hydrogen, carbon, fluorine or combinations thereof. The organic residues may have originated from, for example, photoresist processing, dielectric etch processing, other process steps, or exposure to atmosphere between processing steps. The contaminant region 310 may be a thin layer (as shown in FIG. 3E) over the conductive sub-layer 302 or alternatively, a region that only partially covers the conductive sub-layer 302. The contaminant region may have a thickness less than about 100 Angstroms.

Referring to FIG. 3F, the etch resist 307 may be removed by conventional methods, revealing a top surface 320 of the dielectric layer 304. Referring to FIG. 3G, the contaminant region 310 is then removed or cleaned from the feature 306 using a reactive pre-clean process. One or more process gases are introduced into a processing chamber such as, for example the vacuum chamber 111 of the RPC apparatus 302 shown in FIG. 2 or the applicator 52 of the remote plasma source 50 shown in FIG. 1. The one or more process gases generally comprise a reducing gas, such as, for example, hydrogen (H₂), ammonia (NH₃), or hydrazine (N₂H₂), among other gases capable of reducing contaminants such as metal oxides and the like on a material layer, and combinations thereof.

The one or more process gases generally comprise at least one suppressant gas useful for suppressing reactions between the reducing gas and a dielectric layer exposed to the reducing gas. The suppressant gas may comprise carbon (C), oxygen (O), or nitrogen (N), or combinations thereof. In one embodiment, the suppressant gas comprises two or more elements selected from the group consisting of carbon (C), oxygen (O), or nitrogen (N), and hydrogen (H). For example, the suppressant gas may comprise carbon (C) and oxygen (O). Exemplary suppressant gases comprising carbon (C) and oxygen (O) include carbon monoxide (CO) and carbon dioxide (CO₂). The suppressant gas may comprise carbon (C) and hydrogen (H). Exemplary suppressant gases comprising carbon (C) and hydrogen (H) include methane (CH₄), ethane (C₂H₆), among other hydrocarbons. The suppressant gas may comprise carbon (C) and nitrogen (N). Exemplary suppressant gases comprising carbon (C) and nitrogen (N) include 3-methyl pyridine (C₆H₇N), or acrylonitrile (C₃H₄N), among others gases. The suppressant gas may comprise hydrogen (H), or oxygen (O), such as water vapor (H₂O). Other suitable suppressant gases may be devised by using the above combinations.

The above discussion details embodiments of the invention in which the process gas comprises a reducing gas for reducing contaminants and one or more suppressant gases for suppressing reactions between the reducing gas and an exposed dielectric layer. In an alternative embodiment, the process gas comprises a reducing gas that generally does not adversely affect the exposed dielectric layer 304. As such, in this alternative embodiment, it is not essential to incorporate a separate suppressant gas to prevent reactions between the reducing gas and the exposed dielectric layer. In this embodiment, suitable gases that may be included in the reducing gas include oxides of carbon, such as carbon monoxide (CO).

The process gases may further comprise a sputtering gas for enhancing the removal of the contaminant layer 310. The sputtering gas assists in removing the contaminant layer 310 by physically bombarding the contaminant layer 310. The sputtering gas may comprise an inert gas, such as helium (He), neon (Ne), or argon (Ar). Furthermore, the sputtering gas may comprise a gas such as, for example, nitrogen, that may assist in suppressing reactions between the reducing gas and the dielectric layer 304.

The process gases may be ignited into a plasma. In this embodiment, the reducing gas, the at least one suppressant gas, and the sputtering gas may exist in various states, such as, for example, neutral atoms or ions. Generally the plasma includes a reducing species (e.g. hydrogen atoms or ions) and one or more suppressant species. The suppressant species may comprise, for example, atoms or ions of oxygen, hydrogen, nitrogen, or carbon. The suppressant species may comprise charged or uncharged species or fragments of the suppressant gases described above (e.g. charged or uncharged reactive intermediate compounds comprising carbon (C), oxygen (O), or nitrogen (N), and hydrogen (H)).

In order to facilitate the removal of the contaminant layer 310, the pressure of the chamber, such as the chamber 111 may be maintained in a range of about 1 millitorr to about 10 torr. The temperature of the chamber may be selected depending upon the composition of the dielectric layer 304. The temperature of the chamber may be maintained low enough to prevent or reduce sputtering of material from the conductive sub-layer 302 onto a sidewall 322 of the dielectric layer 304. For example, the temperature may be maintained in a range of about 0 degrees Celsius to about 350 degrees Celsius. The one or more process gases may be provided to the chamber 111 at a flow rates in a range of about 1 standard cubic centimeters per second (sccm) to about 5000 sccm.

The relative proportions of the reducing gas, the one or more suppressant gases, and the sputtering gas may be selected depending upon, for example, the composition of the dielectric layer 402 as well as the degree of etch selectivity desired. The reducing gas and the one or more suppressant gases may be present in a reducing gas to suppressant gas ratio that is in a range of about 2% to about 100%.

A high frequency power from about 1 watts (W) to about 5000 W may be applied to the antenna 125 within the chamber 111 in order to ignite the process gases into a plasma. A high frequency power from about a 1W to about 1000 W may be applied to the pedestal, such as the pedestal 122. The exposure of the contaminant layer 310 to the reducing species may last for a period from about 5 seconds to about 60 seconds. During this period, the reducible contaminant reacts with the reducing species. Generally, the reaction products are purged from the chamber 111 through the exhaust outlet 128.

While not wishing to be bound by a particular theory or mechanism of the suppression process, it is believed that the suppressant species may prevent or reduce chemical reactions between carbon or other components in the dielectric layer 304 and the reducing gas. By providing suppressant species as described above, it is believed that reactions that would consume carbon or other components within the dielectric layer 304 are made less thermodynamically favorable and thereby suppressed. It is also believed that in certain cases, the suppressant species may form a transient or permanent protective layer on a surface, such as the sidewall 322 of the dielectric layer 304 that prevents the reducing gas from modifying or reacting with the dielectric layer 304 in such a way that would otherwise result in the dielectric layer 304 having a reduced dielectric constant. In addition to suppressing reactions between the dielectric layer 304 and the reducing species, contacting the dielectric layer 304 with suppressant species, in some cases also improves the adhesion between the dielectric layer 304 and material layers subsequently deposited on the dielectric layer 304.

Referring to FIG. 3H, a conductive layer 312 may be formed over at least one of the features 306 in order to make electrical contact to the underlying conductive sub-layer 302. The conductive layer 312 may be formed by conventional deposition techniques, including, electrochemical plating (ECP), CVD, PVD, among other deposition methods. The conductive layer 312 may comprise copper (Cu), aluminum (Al), or tungsten (W). An optional barrier layer 314 may be formed prior to the deposition in order to prevent or limit diffusion between the conductive layer 312 and the dielectric layer 304. The barrier layer 314 may be any suitable material, such as titanium, tantalum, titanium nitride, tantalum nitride, or combinations thereof. An optional seed layer 316 may be formed on the barrier layer to facilitate deposition of the conductive layer 312. The seed layer may have a composition similar to the conductive layer 312 formed thereon. The seed layer 316 may be formed by, for example, electroless plating, CVD, among other methods. The conductive layer may be planarized, as shown in FIG. 31 to form conductive features 318.

In another embodiment of the invention, the dielectric layer 304 is pretreated with a suppressant gas composition prior to removing the contaminant layer 310. This pre-treatment step may be performed, for example, after etching the features 306 in the dielectric layer 304 (described above with reference to FIG. 3D) and before the removal of the contaminant layer (described above with reference to FIG. 3G).

The pre-treatment step comprises contacting the dielectric layer 304 with one or more suppressant species. The suppressant species generally have a composition as described above for the pre-cleaning process. The suppressant species may be formed by igniting a suppressant gas into a plasma. The process variables (e.g., flow rates, temperature, pressure, high frequency power and bias power) may be similar to those described above.

Pre-treatment of the dielectric layer 302 may obviate the need for subsequently contacting the dielectric layer with suppressant species. For example, after pre-treatment of the dielectric layer 302, the contaminant layer 310 may be removed using a pre-clean process in which reducing species and no suppressant species are supplied to the chamber. Alternatively, to enhance the protection of the dielectric layer 302 during the exposure to the reducing species, the contaminant layer 310 (and the exposed dielectric layer 302) may be contacted with both reducing species and suppressant species.

While the foregoing is directed to embodiments of the present invention, other and further embodiments of the invention may be devised without departing from the basic scope thereof, and the scope thereof is determined by the claims that follow.

1. A method of removing a contaminant from a surface of a material layer, comprising:
exposing a dielectric layer to one or more suppressant species for suppressing reactions between the dielectric layer and a reducing species; and
exposing the contaminant and the dielectric layer to the reducing species to remove the contaminant from the surface of the material layer.

2. The method of claim 1 wherein the dielectric layer is simultaneously exposed to the reducing species and the suppressant species.

3. The method of claim 1 wherein the reducing species includes hydrogen.

4. The method of claim 1 wherein the one or more suppressant species includes at least one element selected from the group consisting of carbon, oxygen, and nitrogen.

5. The method of claim 1 wherein the one or more suppressant species includes at least two elements selected from the group consisting of carbon, oxygen, hydrogen, and nitrogen.

6. The method of claim 1 further comprising reacting the reducing species with the contaminant to remove the contaminant from the surface of the material layer.

7. The method of claim 1 further comprising using a sputtering gas to sputter the contaminant from the surface of the material layer.

8. The method of claim 7 wherein the sputtering gas is selected from the group consisting of helium, argon, neon, nitrogen, and combinations thereof.

9. The method of claim 1 wherein the contaminant comprises a chemical species selected from the group consisting of oxygen, carbon, hydrogen, fluorine, and combinations thereof.

10. The method of claim 1 wherein the contaminant comprises a metal oxide.

11. The method of claim 1 wherein the contaminant comprises residue from an etch process.

12. The method of claim 1 wherein the dielectric layer comprises a low K dielectric material.

13. The method of claim 12 wherein the low K dielectric material is selected from the group consisting of fluorine-doped silicate glass (FSG), porous oxide materials, silsesquioxanes, organosilicates, parylene, fluorinated materials, and combinations thereof.

14. The method of claim 1 wherein the dielectric layer has a dielectric constant, and the suppressant gas mitigates an increase in the dielectric constant resulting from contact between the reducing gas and the dielectric layer.

15. The method of claim 1 wherein the dielectric layer has a carbon content, and the suppressant gas mitigates a reduction in the carbon content resulting from contact between the reducing gas and the dielectric layer.

16. The method of claim 1 wherein the material layer is a conductive layer.

17. The method of claim 1 wherein the material layer comprises a material selected from the group consisting of copper (Cu), aluminum (Al), or tungsten (W).

18. A method of removing a reducible contaminant from a surface of a conductive layer, comprising:
exposing a low K dielectric layer to one or more suppressant species for suppressing reactions between the low K dielectric layer and a reducing species, wherein the suppressant species comprise at least two elements selected from the group consisting of carbon, oxygen, hydrogen, nitrogen; and
exposing the contaminant and the dielectric layer to the reducing species.

19. A method for use within a processing chamber of removing a contaminant from a surface of a material layer on a substrate, wherein the substrate has an exposed dielectric layer thereon, the method comprising:
suppressing a reaction between the dielectric layer and a reducing species; and
providing the reducing species to the chamber to remove the contaminant from the material layer.

20. The method of claim 19 further comprising providing one or more suppressant species to the chamber.

21. The method of claim 19 wherein the reducing species includes a species selected from the group consisting of hydrogen, an oxide of carbon, and combinations thereof.

22. The method of claim 20 wherein the one or more suppressant species includes at least one element selected from the group consisting of carbon, oxygen, hydrogen, and nitrogen.

23. The method of claim 20 wherein the one or more suppressant species includes at least two elements selected from the group consisting of carbon, oxygen, hydrogen, and nitrogen.

24. The method of claim 19 further comprising using a sputtering gas to sputter the contaminant from the surface of the material layer.

25. The method of claim 24 wherein the sputtering gas is selected from the group consisting of helium, argon, neon, nitrogen, and combinations thereof.

26. The method of claim 19 wherein the contaminant comprises a chemical species selected from the group consisting of oxygen, carbon, hydrogen, fluorine, and combinations thereof.

27. The method of claim 19 wherein the contaminant comprises a metal oxide.

28. The method of claim 19 wherein the contaminant comprises residue from an etch process.

29. The method of claim 19 wherein the dielectric layer comprises a low K dielectric material.

30. The method of claim 29 wherein the low K dielectric material is selected from the group consisting of fluorine-doped silicate glass (FSG), porous oxide materials, silsesquioxanes, organosilicates, parylene, fluorinated materials, and combinations thereof.

31. The method of claim 19 wherein the dielectric layer has a dielectric constant, and the suppressant gas mitigates an increase in the dielectric constant resulting from contact between the reducing gas and the dielectric layer.

32. The method of claim 19 wherein the dielectric layer has a carbon content, and the suppressant gas mitigates a reduction in the carbon content resulting from contact between the reducing gas and the dielectric layer.

33. The method of claim 19 wherein the material layer is a conductive layer.

34. The method of claim 19 wherein the material layer comprises a material selected from the group consisting of copper (Cu), aluminum (Al), or tungsten (W).

35. The method of claim 19 wherein the providing of the reducing species and the suppressing of the reaction between the dielectric layer and the reducing species occur simultaneously.

36. A method for use in a processing chamber of removing a reducible contaminant from a surface of a conductive layer, wherein the conductive layer and an exposed low K dielectric layer are formed on a substrate, and wherein the contaminant comprises one or more of metal oxide, a carbon containing material, a fluorine containing material, the method comprising:
providing one or more suppressant species to the chamber, wherein the one or more suppressant species include at least two elements selected from the group consisting of carbon, oxygen, hydrogen, and nitrogen;
using the one or more suppressant species to suppress a reaction between the low K dielectric layer and a reducing species; and
providing reducing species to the chamber to remove the reducible contaminant.

37. A method of cleaning a surface of a material layer having a reducible contaminant thereon, comprising:
exposing the surface of the material layer to a plasma, wherein the plasma comprises a reducing species and one or more suppressant species, the suppressant species for suppressing reactions between an exposed dielectric layer and the reducing species; and
cleaning the surface of the material layer.

38. The method of claim 37 wherein the reducing species includes hydrogen.

39. The method of claim 37 wherein the one or more suppressant species includes at least one element selected from the group consisting of carbon, oxygen, hydrogen, nitrogen.

40. The method of claim 37 wherein the one or more suppressant species includes at least two elements selected from the group consisting of carbon, oxygen, hydrogen, and nitrogen.

41. The method of claim 37 further comprising reacting the reducing species with the reducible contaminant to remove the reducible contaminant from the surface of the material layer.

42. The method of claim 37 further comprising using a sputtering gas to sputter the reducible contaminant from the surface of the material layer.

43. The method of claim 42 wherein the sputtering gas is selected from the group consisting of helium, argon, neon, nitrogen, and combinations thereof.

44. The method of claim 37 wherein the reducible contaminant comprises a chemical species selected from the group consisting of oxygen, carbon, hydrogen, fluorine, and combinations thereof.

45. The method of claim 37 wherein the reducible contaminant comprises a metal oxide.

46. The method of claim 37 wherein the contaminant comprises residue from an etch process.

47. The method of claim 37 wherein the exposed dielectric layer comprises a low K dielectric material.

48. The method of claim 47 wherein the low K dielectric material is selected from the group consisting of fluorine-doped silicate glass (FSG), porous oxide materials, silsesquioxanes, organosilicates, parylene, fluorinated materials, and combinations thereof.

49. The method of claim 37 wherein the exposed dielectric layer has a dielectric constant, and the suppressant gas mitigates an increase in the dielectric constant resulting from contact between the reducing gas and the exposed dielectric layer.

50. The method of claim 37 wherein the exposed dielectric layer has a carbon content, and the suppressant gas mitigates a reduction in the carbon content resulting from contact between the reducing gas and the exposed dielectric layer.

51. The method of claim 37 wherein the material layer is a conductive layer.

52. The method of claim 37 wherein the material layer comprises a material from the group consisting of copper (Cu), aluminum (Al), or tungsten (W).

53. A method of cleaning a surface of a conductive sub-layer within a feature formed in a dielectric layer comprising:
forming a plasma comprising a reducing species and one or more suppressant species for suppressing reactions between the reducing species and the dielectric layer; and
cleaning the surface of the conductive sub-layer.

54. The method of claim 53 wherein the cleaning comprises removing a reducible contaminant on the surface of the conductive sub-layer.

55. The method of claim 53 wherein the dielectric layer is simultaneously exposed to the reducing species and the one or more suppressant species.

56. The method of claim 53 wherein the reducing species includes hydrogen.

57. The method of claim 53 wherein the one or more suppressant species includes at least one element selected from the group consisting of carbon, oxygen, and nitrogen.

58. The method of claim 53 wherein the one or more suppressant species includes at least two elements selected from the group consisting of carbon, oxygen, hydrogen, and nitrogen.

59. The method of claim 54 further comprising reacting the reducing species with the reducible contaminant to remove the reducible contaminant from the surface of the material layer.

60. The method of claim 54 further comprising using a sputtering gas to sputter the reducible contaminant from the surface of the material layer.

61. The method of claim 60 wherein the sputtering gas is selected from the group consisting of helium, argon, neon, nitrogen, and combinations thereof.

62. The method of claim 54 wherein the reducible contaminant comprises a chemical species selected from the group consisting of oxygen, carbon, hydrogen, fluorine, and combinations thereof.

63. The method of claim 54 wherein the reducible contaminant comprises a metal oxide.

64. The method of claim 54 wherein the reducible contaminant comprises residue from an etch process.

65. The method of claim 53 wherein the dielectric layer comprises a low K dielectric material.

66. The method of claim 65 wherein the low K dielectric material is selected from the group consisting of fluorine-doped silicate glass (FSG), porous oxide materials, silsesquioxanes, organosilicates, parylene, fluorinated materials, and combinations thereof.

67. The method of claim 53 wherein the dielectric layer has a dielectric constant, and the suppressant gas mitigates an increase in the dielectric constant resulting from contact between the reducing gas and the dielectric layer.

68. The method of claim 53 wherein the dielectric layer has a carbon content, and the suppressant gas mitigates a reduction in the carbon content resulting from contact between the reducing gas and the dielectric layer.

69. The method of claim 53 wherein the conductive sub-layer comprises a material selected from the group consisting of copper (Cu), aluminum (Al), or tungsten (W).

70. A method of cleaning a surface of a conductive sub-layer within a feature formed in a dielectric layer comprising:
providing a gas mixture to a chamber, wherein the gas mixture comprises a reducing gas and one or more suppressant gases, and wherein the one or more suppressant gases comprise at least one element selected from the group consisting of carbon, oxygen, and nitrogen;
igniting the gas mixture into a plasma; and
cleaning a reducible contaminant from the surface of the conductive sub-layer, wherein the reducible contaminant comprises a material selected from the group consisting of a metal oxide, a carbon-containing material, a fluorine-containing material, and combinations thereof from the surface of the conductive sub-layer.

71. A method of removing a reducible contaminant from a surface of a conductive layer, wherein the conductive layer is formed within a feature formed in a dielectric layer, comprising:
providing a gas mixture to a chamber, wherein the gas mixture comprises a reducing gas, a sputtering gas, and one or more suppressant gases, wherein the one or more suppressant gases comprise at least two elements selected from the group consisting of carbon, oxygen, hydrogen and nitrogen;
igniting the gas mixture into a plasma; and
reacting the reducible contaminant with the reducing gas; and
sputtering the reducible contaminant with the sputtering gas to remove the reducible contaminant.

72. The method of claim 71 wherein the reducible contaminant has a thickness less than about 100 Angstroms.

73. A method of removing a contaminant from a surface of a material layer, comprising:
exposing the contaminant to an oxide of carbon; and
reacting the contaminant with the oxide of carbon to remove the contaminant from the surface of the material layer.

74. The method of claim 73 wherein the oxide of carbon comprises carbon monoxide.

75. The method of claim 73 further comprising using a sputtering gas to sputter the contaminant from the surface of the material layer.

76. The method of claim 75 wherein the sputtering gas is selected from the group consisting of helium, argon, neon, nitrogen, and combinations thereof.

77. The method of claim 73 wherein the contaminant comprises a chemical species selected from the group consisting of oxygen, carbon, hydrogen, fluorine, and combinations thereof.

78. The method of claim 73 wherein the contaminant comprises a metal oxide.

79. The method of claim 73 wherein the contaminant comprises residue from an etch process.

80. The method of claim 73 wherein the material layer is a conductive layer.

81. The method of claim 73 wherein the material layer is formed within a feature of a dielectric layer.

82. The method of claim 73 wherein the material layer comprises a material selected from the group consisting of copper (Cu), aluminum (Al), or tungsten (W).

83. The method of claim 81 wherein dielectric layer has a dielectric constant less than about 4.

84. A method of removing a reducible contaminant from a surface of a conductive sub-layer, wherein the conductive sub-layer is formed within a low K dielectric layer, the method comprising:
exposing the reducible contaminant and the low-K dielectric layer to an oxide of carbon; and
removing the reducible contaminant, wherein the reducible contaminant comprises a material selected from the group consisting of a metal oxide, a carbon-containing material, a fluorine-containing material, and combinations thereof from the surface of the conductive sub-layer.

85. A method for pre-treating a dielectric layer, comprising:
contacting the dielectric layer with one or more suppressant gases for suppressing reactions between the dielectric layer and a reducing gas; and
contacting the dielectric layer with a reducing gas.

86. The method of claim 85 wherein the contacting of the dielectric layer with the reducing gas takes place during a period of time after the contacting the dielectric layer with the one or more suppressant gases is completed.

87. The method of claim 85 wherein the dielectric layer has a dielectric constant less than about 4.

88. The method of claim 85 wherein the one or more suppressant gases form a passivation layer on the surface of the dielectric layer.

89. A method of forming an interconnect for an integrated circuit, comprising:
depositing a dielectric layer on a substrate wherein the substrate includes a conductive sub-layer;
etching a feature within the dielectric layer to expose a surface of the conductive sub-layer;
cleaning the surface of the conductive sub-layer with a plasma comprising a reducing gas and one or more suppressant gases for suppressing reactions between the reactant gas and the dielectric layer; and
depositing conductive material within the feature.

90. The method of claim 89 wherein the reducing species includes hydrogen.

91. The method of claim 89 wherein the one or more suppressant gases includes at least one element selected from the group consisting of carbon, oxygen, and nitrogen.

92. The method of claim 89 wherein the one or more suppressant gases includes at least two elements selected from the group consisting of carbon, oxygen, hydrogen, nitrogen.

93. The method of claim 89 further comprising using a sputtering gas to sputter the contaminant from the surface of the material layer.

94. The method of claim 93 wherein the sputtering gas is selected from the group consisting of helium, argon, neon, nitrogen, and combinations thereof.

95. The method of claim 89 wherein the cleaning comprises removing a reducible contaminant from the surface of the conductive sub-layer.

96. The method of claim 95 wherein the reducible contaminant comprises a chemical species selected from the group consisting of oxygen, carbon, hydrogen, fluorine, and combinations thereof.

97. The method of claim 95 wherein the reducible contaminant comprises a metal oxide.

98. The method of claim 95 wherein the reducible contaminant comprises residue from an etch process.

99. The method of claim 89 wherein the dielectric layer comprises a low K dielectric material.

100. The method of claim 99 wherein the low K dielectric material is selected from the group consisting of fluorine-doped silicate glass (FSG), porous oxide materials, silsesquioxanes, organosilicates, parylene, fluorinated materials, and combinations thereof.

101. The method of claim 89 wherein the dielectric layer has a dielectric constant, and the suppressant gas mitigates an increase in the dielectric constant resulting from contact between the reducing gas and the dielectric layer.

102. The method of claim 89 wherein the dielectric layer has a carbon content, and the suppressant gas mitigates a reduction in the carbon content resulting from contact between the reducing gas and the dielectric layer.

103. The method of claim 89 wherein the conductive sub-layer comprises a material selected from the group consisting of copper (Cu), aluminum (Al), or tungsten (W).

104. A method of forming an interconnect for an integrated circuit, comprising:
depositing a low K dielectric layer on a substrate, wherein the substrate includes a conductive sub-layer;
etching a feature within the low K dielectric layer to expose a surface of the conductive sub-layer;
cleaning a reducible contaminant, wherein the reducible contaminant comprises a material selected from the group consisting of a metal oxide, a carbon-containing material, a fluorine-containing material, and combinations thereof, from a surface of the conductive sub-layer with a plasma comprising a reducing gas and one or more suppressant gases for suppressing reactions between the reactant gas and the dielectric layer, wherein the one or more suppressant gases comprise at least two elements selected from the group consisting of carbon, oxygen, hydrogen, and nitrogen; and
depositing conductive material within the feature.
